(19) United States
(12) Patent Application Publication
(10) Pub. No.: US 2026/0231448 A1
(43) Pub. Date: Aug. 6, 2026

(54) CAPACITOR DETECTION STRUCTURE AND CAPACITOR DETECTION METHOD

(71) Applicant: Winbond Electronics Corp., Taichung City (TW)

(72) Inventors: Chung-Ling Yeh, Tainan (TW); Chun-Chiao Tseng, Taichung City (TW)

(73) Assignee: Winbond Electronics Corp., Taichung City (TW)

(21) Appl. No.: 19/396,355

(22) Filed: Nov. 21, 2025

(30) Foreign Application Priority Data
Feb. 4, 2025 (TW) 114104035

(51) Int. Cl. H10D 1/68; G01R 31/27; H10D 1/00

(52) U.S. Cl. CPC H10D 1/716; G01R 31/275; H10D 1/043

(57) ABSTRACT

A capacitor detection structure, including a wafer with a scribe line and a detection structure on the scribe line. The detection structure includes a route, multiple capacitor lower electrodes, a high dielectric constant dielectric layer, and a support structure. The route is disposed in the scribe line of the wafer. The capacitor lower electrodes are located on the scribe line. In the capacitor lower electrodes, a first part is connected to the route, and a second part is not connected to the route. The high dielectric constant dielectric layer is located on an outer sidewall and an inner sidewall of the capacitor lower electrodes. The support structure is connected to a top sidewall of each of the capacitor lower electrodes and has multiple openings. A top surface of the support structure does not have the high dielectric constant dielectric layer.

### CROSS-REFERENCE TO RELATED APPLICATION

This application claims the priority benefit of Taiwan application serial no. 114104035, filed on February 4, 2025. The entirety of the above-mentioned patent application is hereby incorporated by reference herein and made a part of this specification.

### BACKGROUND

### Technical Field

The disclosure relates to a semiconductor detection technology, and in particular to a capacitor detection structure and a capacitor detection method.

### Description of Related Art

In existing semiconductor elements, capacitors generally adopt a tall structure to increase capacitance. Therefore, each layer in the capacitor structure needs to be inspected to ensure that adjacent electrodes do not short-circuit. Common detection tools include electron beam inspection tools.

However, in electron beam inspection for stress caused by a high dielectric constant (high-k) dielectric layer, high noise makes it difficult to determine the location and position of a short circuit.

### SUMMARY

The disclosure provides a capacitor detection structure, which is a detection structure that allows defect locations to be accurately detected.

The disclosure also provides a capacitor detection method, which improves the accuracy of identifying defect locations.

A capacitor detection structure of the disclosure includes a wafer having a scribe line and a detection structure located on the scribe line of the wafer. The detection structure includes a route, a plurality of capacitor lower electrodes, a high dielectric constant dielectric layer, and a support structure. The route is disposed in the scribe line of the wafer. The plurality of capacitor lower electrodes are located on the scribe line. A first part of the plurality of capacitor lower electrodes is connected to the route, and a second part of the plurality of capacitor lower electrodes is not connected to the route. The high dielectric constant dielectric layer is located on an outer sidewall and an inner sidewall of the plurality of capacitor lower electrodes. The support structure is connected to a top sidewall of each of the plurality of capacitor lower electrodes and has a plurality of openings. A top surface of the support structure does not have the high dielectric constant dielectric layer.

A capacitor detection method of the disclosure includes the following steps. A wafer is provided. A detection structure is formed in a scribe line of the wafer. An electron beam inspection is performed on the detection structure. In this method, a method of forming the detection structure includes the following steps. A route is formed in the scribe line of the wafer. At least one oxide layer and at least one silicon nitride layer are sequentially formed on the scribe line. A plurality of through vias are formed in the oxide layer and the silicon nitride layer. A first part of the plurality of through vias exposes a part of the route, and a second part of the plurality of through vias does not expose the route. A conductive material is then deposited to cover side surfaces of the plurality of through vias and a surface of the at least one silicon nitride layer. A plurality of openings are formed in the silicon nitride layer, exposing the oxide layer. A remaining part of the silicon nitride layer becomes the support structure. The oxide layer is then removed, followed by removing the conductive material on a top surface of the support structure. A remaining part of the conductive material becomes the plurality of capacitor lower electrodes for detection. A high dielectric constant dielectric layer is deposited entirely over the support structure and on the outer sidewalls and inner sidewalls of the plurality of capacitor lower electrodes. The high dielectric constant dielectric layer on the top surface of the support structure is then removed by etching.

Based on the above, the high dielectric constant dielectric layer on the topmost part of the capacitor detection structure is removed, significantly reducing background noise during detection and thereby improving the accuracy of identifying defect locations.

### BRIEF DESCRIPTION OF THE DRAWINGS

FIG. 1 is a top view of a capacitor detection structure in a first embodiment of the disclosure.

FIG. 2 is a cross-sectional view of a capacitor detection structure in the first embodiment of the disclosure.

FIG. 3 is a step diagram of a capacitor detection method in a second embodiment of the disclosure.

FIGS. 4A to 4F are schematic cross-sectional diagrams illustrating the manufacturing process of forming a detection structure in the method of the second embodiment.

### DESCRIPTION OF THE EMBODIMENTS

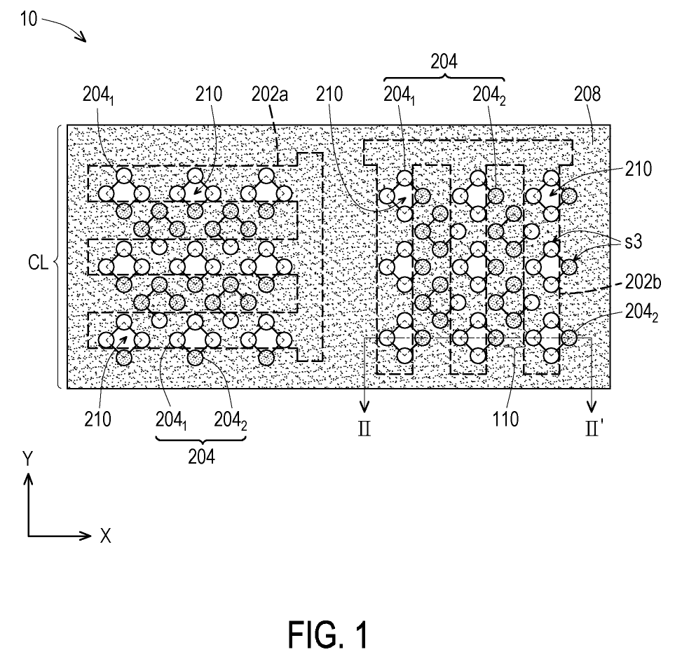

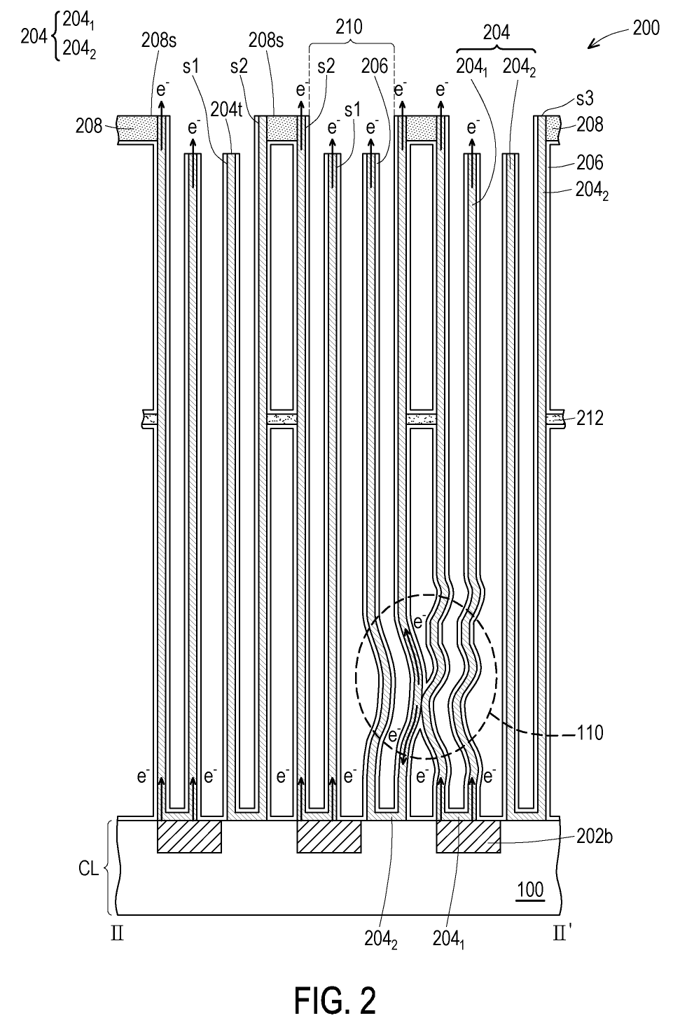

Referring to FIG. 1 and FIG. 2, FIG. 2 is a cross-sectional view along the II-II’ line of a capacitor detection structure shown in FIG. 1.

A capacitor detection structure 10 includes a wafer 100 and a detection structure 200 located on a scribe line CL of the wafer 100. The detection structure 200 includes routes 202a and 202b, a plurality of capacitor lower electrodes 204, a high dielectric constant (high-k) dielectric layer 206, and a support structure 208. The routes 202a and 202b are disposed in the scribe line CL of the wafer 100 and may be grounded. In some embodiments, the route 202a includes a plurality of conductive lines extending in an X direction, and the route 202b includes a plurality of conductive lines extending in a Y direction. Therefore, the electrical properties of a dense capacitor structure may be comprehensively detected to identify a structural defect 110. The capacitor lower electrodes 204 are located on the scribe line CL, wherein a first part 204₁ of the capacitor lower electrodes 204 is connected to the routes 202a and 202b, and a second part 204₂ of the capacitor lower electrodes 204 is not connected to the routes 202a and 202b. Therefore, the first part 204₁ connected to the routes 202a and 202b allows electrons e⁻ to flow in, while the second part 204₂ not connected to the routes 202a and 202b does not allow electrons e⁻ to flow in. Since the detection structure 200 is used to detect whether a structure of a single electrode has a defect, the capacitor lower electrodes 204 are electrically isolated from each other. However, it should be understood that a capacitor actually formed in the wafer may use all the capacitor lower electrodes 204 in FIG. 1 as a single lower electrode, with a route connected to a top 204t of each capacitor lower electrode 204. In another embodiment, a capacitor actually formed in the wafer may also use only one or several capacitor lower electrodes 204 in FIG. 1 as a single lower electrode.

Referring again to FIG. 2, the high-k dielectric layer 206 is located on an outer sidewall s1 and an inner sidewall s2 of the capacitor lower electrode 204. The material of the high-k dielectric layer 206 includes, but is not limited to, zirconium oxide, aluminum oxide, or other high-k dielectric materials. The support structure 208 is connected to a top sidewall of each capacitor lower electrode 204 at the top 204t and has a plurality of openings 210, wherein a top surface 208s of the support structure 208 does not have the high-k dielectric layer 206. In some embodiments, if the capacitor lower electrode 204 has a relatively large height, an additional support structure 212 may be provided at a middle portion of the capacitor lower electrode 204. However, the disclosure is not limited thereto. In other embodiments, the support structure 212 may be omitted. Additionally, the top 204t of the capacitor lower electrode 204 has a height difference, and the support structure 208 is located on a higher portion of the top 204t of the capacitor lower electrode 204. Furthermore, a top surface s3 of the capacitor lower electrode 204 also does not have the high-k dielectric layer 206.

Referring again to FIG. 1, in this embodiment, the top surface s3 of each capacitor lower electrode 204 is circular. Each opening 210 of the support structure 208 is square, and four corners of one opening 210 of the support structure 208 are aligned with circular centers of four capacitor lower electrodes 204. However, the disclosure is not limited thereto. In other embodiments, the top surface s3 of the capacitor lower electrode 204 in a top view may be elliptical, square, or other shapes. The opening 210 in a top view may be circular, elliptical, or other shapes. Furthermore, the relative positional relationship between the opening 210 and the capacitor lower electrode 204 may also be adjusted or changed as needed and is not limited to what is shown in FIG. 1.

If the defect 110, such as a short circuit between adjacent capacitor lower electrodes 204, occur due to stress caused by the high-k dielectric layer 206 or other factors, during the electron beam inspection (EBI) process, the detection structure 200 in FIG. 2 will excite secondary electrons in the second part 204₂, which is not connected to the route 202b, and the defect location will be observed as a bright area.

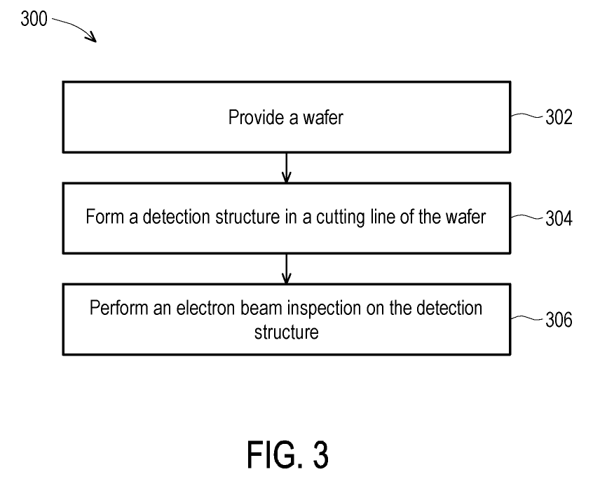

FIG. 3 is a step diagram of a capacitor detection method 300 according to a second embodiment of the disclosure.

In step 302, a wafer is provided, and the wafer has a scribe line.

In step 304, a detection structure is formed in the scribe line of the wafer, wherein the detection structure has a size and process parameters mostly the same as a capacitor actually formed in the wafer, but some processes or structures need to be adjusted according to the detection method. Detailed steps will be described below.

In step 306, an electron beam inspection (EBI) is performed on the detection structure to identify defects in the structure.

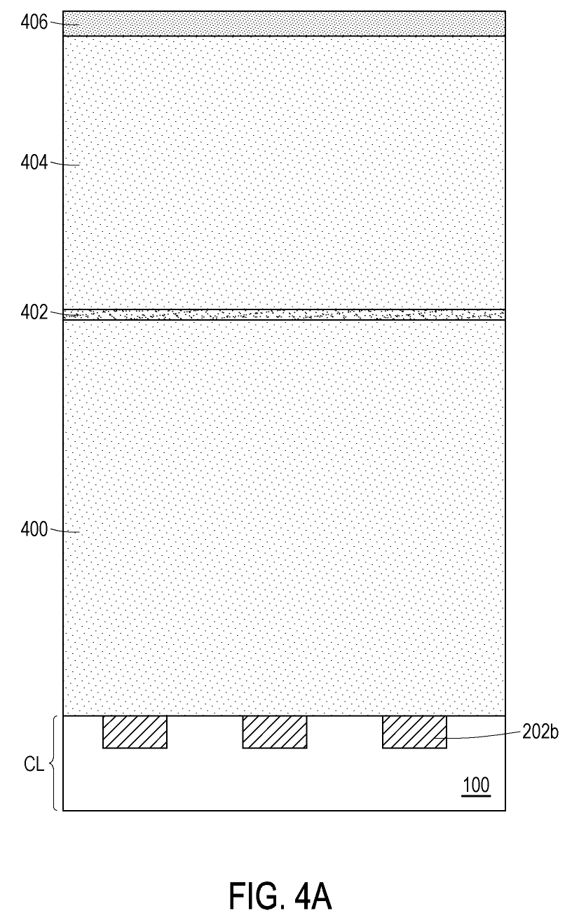

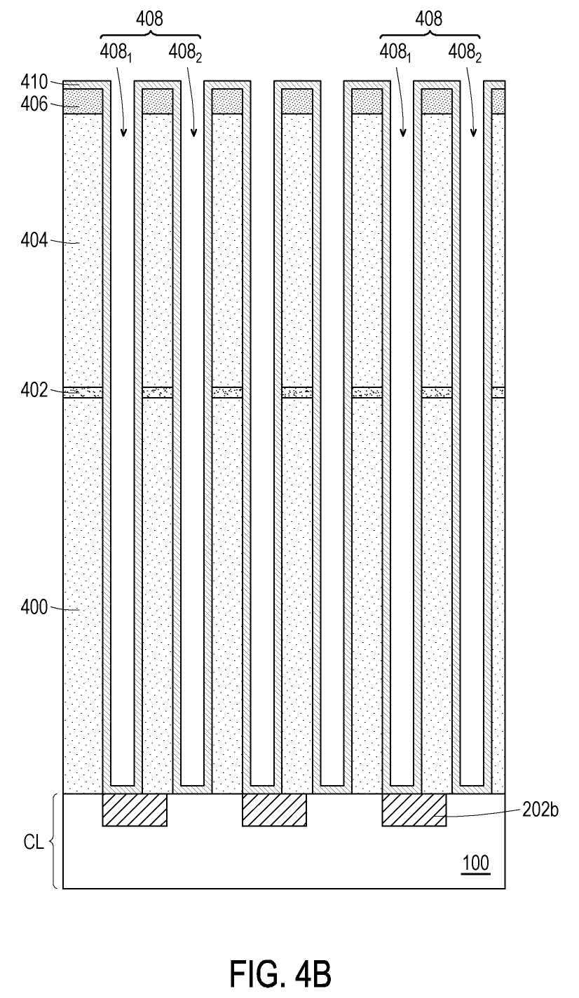

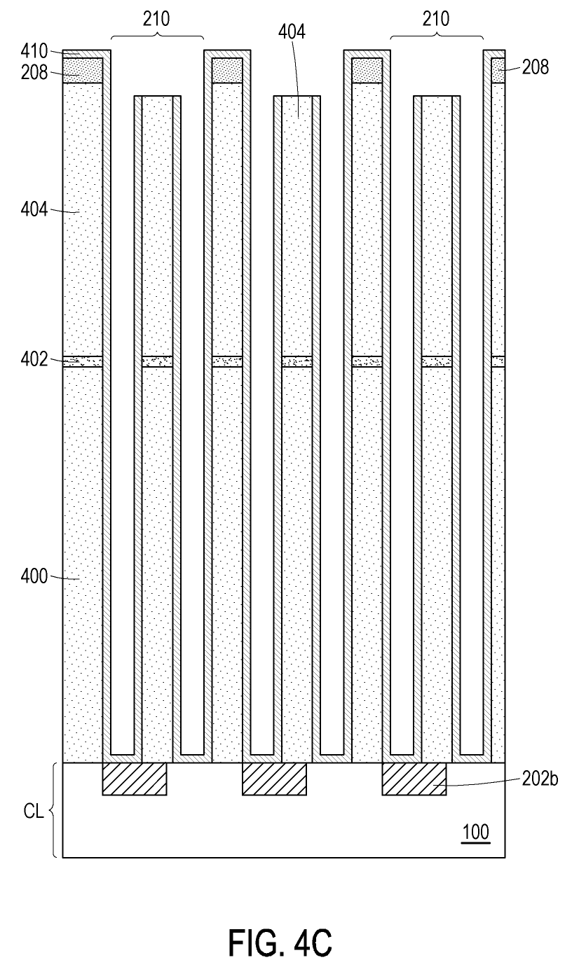

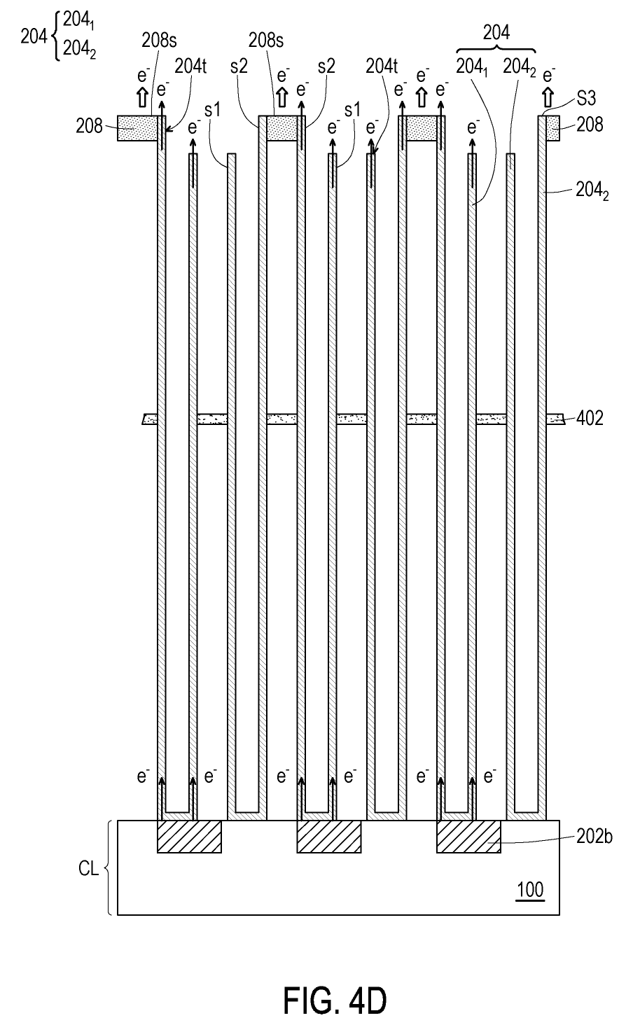

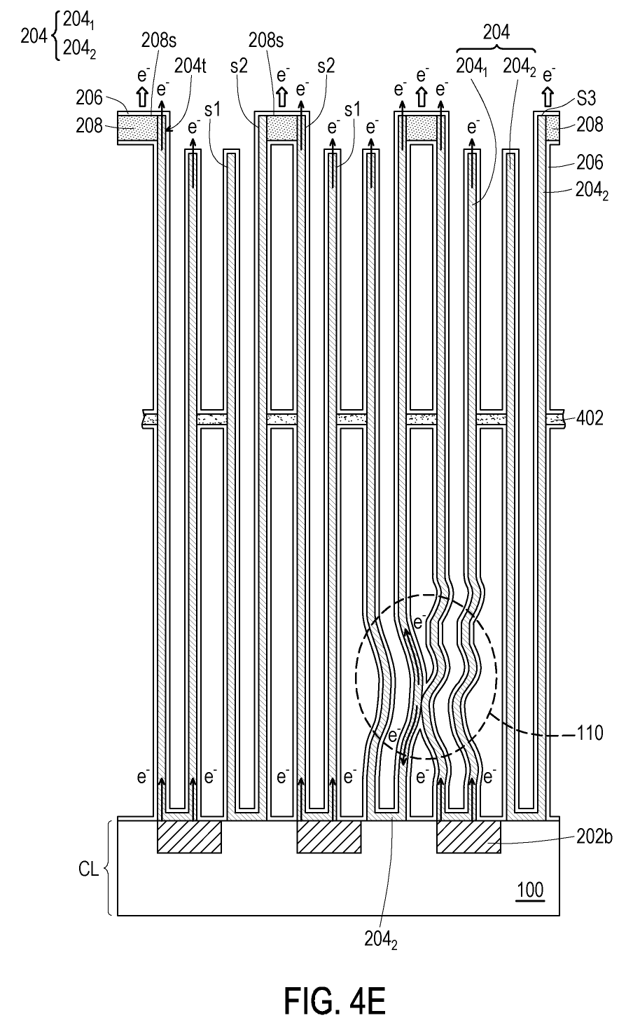

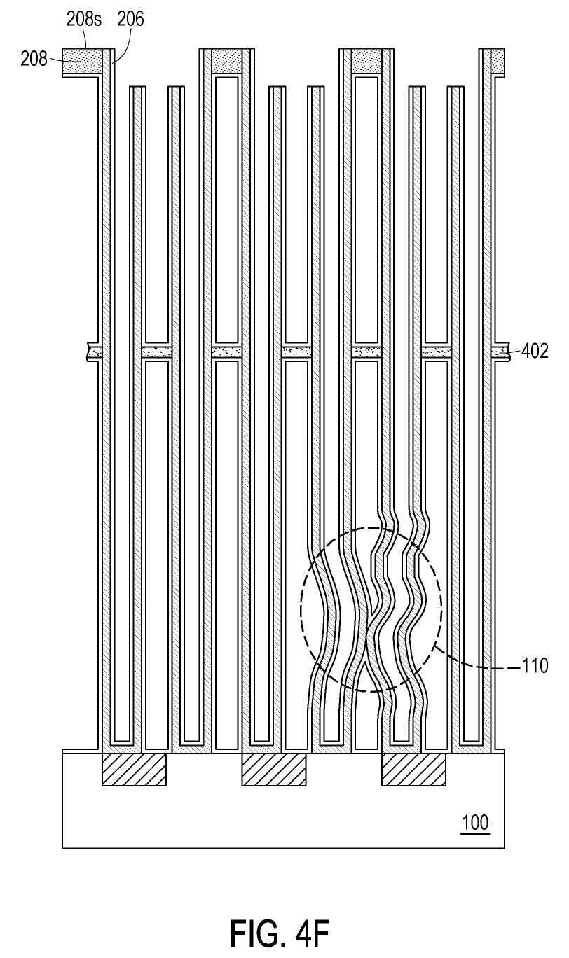

FIGS. 4A to 4F are schematic cross-sectional diagrams illustrating the process flow of step 304 in the method of the second embodiment, wherein the same reference numerals as those in the first embodiment are used to indicate the same or similar parts and components. The related content of the same or similar parts and components may also be referred to in the first embodiment and will not be further described.

Referring to FIG. 4A, the route 202b is formed in the scribe line CL of the wafer 100. Then, an oxide layer 400, a silicon nitride layer 402, an oxide layer 404, and a silicon nitride layer 406 are sequentially formed on the wafer 100. However, the disclosure is not limited thereto. In other embodiments, the oxide layer 404 and the silicon nitride layer 406 may be omitted.

Referring to FIG. 4B, a plurality of through vias 408 are formed to penetrate the oxide layer 400, the silicon nitride layer 402, the oxide layer 404, and the silicon nitride layer 406, wherein a first part 408₁ of the through vias 408 exposes a part of the route 202b, and a second part 408₂ of the through vias 408 does not expose the route 202b. Then, a conductive material 410 is deposited over the entire surface to cover side surfaces of the through vias 408 and a surface of the silicon nitride layer 406.

Referring to FIG. 4C, the openings 210 are formed in the silicon nitride layer 406 of FIG. 4B to simultaneously remove a portion of the silicon nitride layer 406 in FIG. 4B and expose a portion of the oxide layer 404, wherein the remaining silicon nitride layer becomes the support structure 208.

Then, referring to FIG. 4D, a wet process is used to remove all oxide layers, namely the oxide layer 400 and the oxide layer 404 in FIG. 4C, wherein the remaining silicon nitride layer 402 becomes another support structure at the middle section. The wet process includes, but is not limited to, performing an oxide removal process twice. Since the remaining support structure 208 is surrounding each capacitor lower electrode 204, as shown in FIG. 1, sufficient support is provided. Next, the conductive material 410 on the top surface of the support structure 208 is removed, thereby forming the capacitor lower electrodes 204 for detection. The first part 204₁ of the capacitor lower electrode 204 is connected to the route 202b, and the second part 204₂of the capacitor lower electrode 204 is not connected to the route 202b. Therefore, the first part 204₁connected to the route 202b allows electrons e⁻ to flow in, while the second part 204₂ not connected to the route 202b does not allow electrons e⁻ to flow in. After removing the oxide layers, an EBI may first be performed to check whether the capacitor lower electrodes 204 on the scribe line CL are in contact with each other or have collapsed. If the capacitor lower electrodes 204 have no defects, the electrons e⁻ flowing into the first part 204₁ from the route 202b will be excited by the electron beam at the top 204t to emit secondary electrons, displaying bright spots, while the second part 204₂ not connected to the routes 202a and 202b will remain dark. That is, if an area that is originally expected to be detected as dark becomes bright, it indicates a defect at that location.

Then, referring to FIG. 4E, a high-k dielectric layer 206 is entirely deposited over the support structure 208, the support structure 402, and on the outer sidewall s1 and inner sidewall s2 of the capacitor lower electrodes 204. In some embodiments, the high-k dielectric layer 206 is formed by a method including, but not limited to, atomic layer deposition, chemical vapor deposition, or other suitable deposition processes. The formation process of the high-k dielectric layer 206 applies stress to the capacitor lower electrodes 204, which may cause the defect 110. If EBI is performed immediately after this step, the entire top surface 208s of the support structure 208 will appear bright, making it difficult to distinguish the location of defects. This is because the surface area of the high-k dielectric layer 206 on the support structure 208 is much larger than the top surface s3 of the capacitor lower electrodes 204. The high-k dielectric layer 206 has a characteristic of accumulating charges. Therefore, when an electron beam emitted during the EBI process enters this large-area high-k dielectric layer 206, charges accumulate within it. The accumulated charges are then excited by subsequent electron beams, generating secondary electrons, making it difficult to identify the location of the defect 110 in an image where the background appears bright.

Therefore, referring to FIG. 4F, the high-k dielectric layer 206 on the top surface 208s of the support structure 208 needs to be removed by etching. In some embodiments, the method of etching to remove the high-k dielectric layer 206 on the top surface 208s of the support structure 208 may use a time mode to control the termination of etching. In some embodiments, gases such as Cl₂ (chlorine) and BCl₃ (boron trichloride) may be used to etch the high-k dielectric layer 206. Additionally, before etching to remove the high-k dielectric layer 206 on the top surface 208s of the support structure 208, a patterned photoresist (not shown) may first be formed on the wafer 100 outside the scribe line CL to protect other structures. After etching to remove the high-k dielectric layer 206 on the top surface 208s of the support structure 208, an ashing and cleaning process may be subsequently performed to completely remove the patterned photoresist.

When the top surface 208s of the support structure 208 does not have the high-k dielectric layer 206, the electron beam does not accumulate in this area. Therefore, after performing EBI (step 306), the location of the defect 110 may be clearly identified in an image where the background appears dark.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A capacitor detection structure, comprising:
a wafer, having a scribe line; and
a detection structure, disposed on the scribe line of the wafer, wherein the detection structure comprises:
a route, disposed in the scribe line of the wafer;
a plurality of capacitor lower electrodes, located on the scribe line of the wafer, wherein a first part of the plurality of capacitor lower electrodes is connected to the route, and a second part of the plurality of capacitor lower electrodes is not connected to the route;
a high dielectric constant dielectric layer, located on an outer sidewall and an inner sidewall of the plurality of capacitor lower electrodes; and
a support structure, connected to a top sidewall of each of the plurality of capacitor lower electrodes and having a plurality of openings, wherein a top surface of the support structure does not have the high dielectric constant dielectric layer.

2. The capacitor detection structure according to claim 1, wherein the route comprises a plurality of conductive lines extending in an X direction and a plurality of conductive lines extending in a Y direction.

3. The capacitor detection structure according to claim 1, wherein, in a top view, a top surface of the each of the plurality of capacitor lower electrodes is circular.

4. The capacitor detection structure according to claim 3, wherein each of the plurality of openings of the support structure is square.

5. The capacitor detection structure according to claim 4, wherein four corners of one of the plurality of openings are aligned with a plurality of circular centers of four of the plurality of capacitor lower electrodes.

6. The capacitor detection structure according to claim 1, wherein a top of the each of the plurality of capacitor lower electrodes has a height difference, and the support structure is located on a higher part of the top.

7. The capacitor detection structure according to claim 6, wherein a top surface of the each of the plurality of capacitor lower electrodes does not have the high dielectric constant dielectric layer.

8. A capacitor detection method, comprising:
providing a wafer;
forming a detection structure in a scribe line of the wafer; and
performing an electron beam inspection on the detection structure, wherein
a method of forming the detection structure comprises:
forming a route in the scribe line of the wafer;
sequentially forming at least one oxide layer and at least one silicon nitride layer on the scribe line of the wafer;
forming a plurality of through vias in the at least one oxide layer and the at least one silicon nitride layer, wherein a first part of the plurality of through vias exposes a part of the route, and a second part of the plurality of through vias does not expose the route;
depositing a conductive material to cover a side surface of the plurality of through vias and a surface of the at least one silicon nitride layer;
forming a plurality of openings in the at least one silicon nitride layer and exposes a part of the at least one oxide layer, wherein a remaining part of the at least one silicon nitride layer becomes a support structure;
removing the at least one oxide layer;
removing the conductive material on a top surface of the support structure, wherein a remaining part of the conductive material becomes a plurality of capacitor lower electrodes for a detection;
depositing a high dielectric constant dielectric layer entirely over the support structure and an outer sidewall and an inner sidewall of the plurality of capacitor lower electrodes; and
removing the high dielectric constant dielectric layer on the top surface of the support structure by etching.

9. The capacitor detection method according to claim 8, wherein a method of removing the high dielectric constant dielectric layer on the top surface of the support structure by etching comprises using a time mode to control a termination of etching.

10. The capacitor detection method according to claim 9, wherein after removing the at least one oxide layer, the capacitor detection method further comprises performing an electron beam inspection on the plurality of capacitor lower electrodes on the scribe line.

11. The capacitor detection method according to claim 10, wherein after performing the electron beam inspection on the plurality of capacitor lower electrodes, the high dielectric constant dielectric layer is formed.

12. The capacitor detection method according to claim 8, wherein before removing the high dielectric constant dielectric layer on the top surface of the support structure by etching, the capacitor detection method further comprises forming a patterned photoresist on the wafer outside the scribe line.

13. The capacitor detection method according to claim 8, wherein after removing the high dielectric constant dielectric layer on the top surface of the support structure by etching, the capacitor detection method further comprises performing an ashing process and a cleaning process.
